(19) United States
(12) Patent Application Publication
(10) Pub. No.: US 2024/0176049 A1
(43) Pub. Date: May 30, 2024

(54) Optical Device, Optical Module, and Method for Manufacturing Optical Device or Optical Module

(71) Applicant: Daicel Corporation, Osaka (JP)

(72) Inventors: Takahiro Iwahama, Tokyo (JP); Takeshi Fujikawa, Tokyo (JP)

(73) Assignee: Daicel Corporation, Osaka (JP)

(21) Appl. No.: 18/283,768

(22) PCT Filed: Mar. 16, 2022
(86) PCT No.: PCT/JP2022/011798

§ 371 Date: Sep. 22, 2023

(30) Foreign Application Priority Data
Mar. 23, 2021 (JP) 2021-048751

(51) Int. Cl. G02B 3/00; H01S 5/02253

(52) U.S. Cl. CPC G02B 3/0006; G02B 3/0031; H01S 5/02253

(57) ABSTRACT

A technology with a simpler and smaller configuration and capable of suppressing light leakage from an optical module is provided. An optical device (3) includes an optical region (3a) in which an optical element is arranged, at a part of at least one surface of a substrate portion (3b) having a flat plate shape. A peripheral region (3d) in which an optical function as an optical device is not used is provided around the optical region (3a) at the surface, of the substrate portion (3b), provided with the optical region (3a). A light-blocking and diffusing portion (3e) configured to suppress transmission of light or diffuse light is formed at the peripheral region (3d) or a region corresponding to the peripheral region (3d) at an opposite surface of the substrate portion (3b).

### CROSS REFERENCE TO RELATED APPLICATIONS

This application is based upon and claims the benefit of priority of the prior Japanese Patent Application No. 2021-048751, filed on Mar. 23, 2021, and International Patent Application No. PCT/JP2022/011798, filed on Mar. 16, 2022, the entire contents of which are incorporated herein by reference.

### TECHNICAL FIELD

The present invention relates to an optical device, an optical module including an optical device, and a method for manufacturing the same.

### BACKGROUND ART

For example, a known micro lens array has a plurality of lens elements arrayed and is used for an apparatus for illumination, measurement, facial recognition, spatial recognition, and the like (see for example, Patent Documents 1 and 2). By unitizing this micro lens array and a light source to form an optical module, assembly and management of the above-described device that use the micro lens array have been made easy.

On the other hand, a high-intensity light source such as a vertical cavity surface emitting laser (VCSEL laser) light source is often used as a light source used in these optical modules, and an eye-safe problem sometimes occurs. In connection with these problems, a known optical device includes a plurality of regions periodically arranged in a tessellation manner on a surface of the optical device, and each region of the plurality of regions has a random space distribution of a micro structure (see, for example, Patent Document 3).

However, in the optical module as described above, it cannot be said that the structure is sufficiently simple and small in size and that leakage of high-intensity light is sufficiently suppressed. There have been many structures in which an optical device such as a micro lens array is fixed with an adhesive, and the optical performance of the optical device is sometimes affected by flowing out of the adhesive or the like.

### CITATION LIST

### Patent Document

Patent Document 1: WO 2005/103795
Patent Document 2: WO 2015/182619
Patent Document 3: JP 2020-173422 A

### SUMMARY OF INVENTION

### Technical Problem

The technology of the present disclosure has been made in view of the above circumstances, and an object thereof is to provide a technology with a simpler and smaller configuration and capable of suppressing light leakage from an optical module.

### Solution to Problem

In order to solve the above-described problem, an optical device according to the present disclosure is an optical device including an optical region in which an optical element is arranged, at a part of at least one surface of a substrate portion having a flat plate shape, in which a peripheral region in which an optical function as an optical device is not used is provided around the optical region at a surface, of the substrate portion, provided with the optical region, and a light-blocking and diffusing portion configured to suppress transmission of light or diffuse light is formed in the peripheral region or a region corresponding to the peripheral region at an opposite surface of the substrate portion.

More specifically, the optical device includes: an optical region in which an optical element is arranged, at a part of at least one surface of a substrate portion having a flat plate shape; a peripheral region in which the optical element is not arranged, the peripheral region being provided around the optical region at a surface, of the substrate portion, provided with the optical region; and a light-blocking and diffusing portion provided at the peripheral region and/or a region corresponding to the peripheral region at an opposite surface of the substrate portion, the light-blocking and diffusing portion being configured to suppress transmission of light or diffuse light.

Here, in the substrate portion, the optical region may be formed at a surface recessed with respect to the peripheral region.

The optical element may be a lens element, and the optical region may be a lens region in which a plurality of the lens elements are arrayed.

The light-blocking and diffusing portion may have a film of a photoresist material formed at the peripheral region and/or the region corresponding to the peripheral region at the opposite surface of the substrate portion.

The light-blocking and diffusing portion may include a roughened surface in which surface roughness of the peripheral region and/or the region corresponding to the peripheral region at the opposite surface of the substrate portion is larger than that of a side surface of the substrate portion.

An optical module according to the present disclosure is an optical module including: the optical device described above; a light source configured to cause light to be incident on the optical device; and a holding member holding the optical device and the light source, in which the holding member includes a base portion to which the light source is fixed and a side wall portion to which the optical device is fixed, the side wall portion is provided with a placement surface at which the peripheral region of the optical device is placed, and a predetermined adhesive is interposed between the peripheral region and the placement surface.

An upper end of the side wall portion may be formed to be at the same height as an upper surface of the optical device or lower than the upper surface of the optical device.

The predetermined adhesive may have a light-blocking property and form the light-blocking and diffusing portion.

A method for manufacturing an optical device according to the present disclosure is a method for manufacturing an optical device including an optical region in which an optical element is arranged, at a part of at least one surface of a substrate portion having a flat plate shape, the method including: forming, with integral molding, the substrate portion having the flat plate shape, the optical region, and a peripheral region that is arranged around the optical region and in which an optical function as the optical device is not used; and forming a light-blocking and diffusing portion at the peripheral region and/or a region corresponding to the peripheral region at an opposite surface of the substrate portion, the light-blocking and diffusing portion being configured to suppress transmission of light or diffuse light.

The forming of the light-blocking and diffusing portion may be performed simultaneously with the forming, and in the forming, a roughened surface in which surface roughness of the peripheral region and/or the region corresponding to the peripheral region at the opposite surface of the substrate portion is larger than that of a side surface of the substrate portion may be molded as the light-blocking and diffusing portion.

The forming of the light-blocking and diffusing portion may be performed after the forming, and may include forming a film of a photoresist material by photolithography at a surface of the peripheral region and/or the region corresponding to the peripheral region at the opposite surface of the substrate portion, the peripheral region and the substrate portion having been molded in the forming.

The forming of the light-blocking and diffusing portion may be performed after the forming, and may include roughening a surface of the peripheral region and/or the region corresponding to the peripheral region at the opposite surface of the substrate portion, the peripheral region and the substrate portion having been molded in the forming.

A method for manufacturing an optical module according to the present disclosure is a method for manufacturing an optical module, the method including: applying the predetermined adhesive to the placement surface; and placing and fixing the optical device at the placement surface applied with the predetermined adhesive.

In the method for manufacturing an optical module, the predetermined adhesive may have a light-blocking property.

Note that, in the present disclosure, as long as possible, techniques for solving the above-mentioned problems can be used in combination.

### Advantageous Effects of Invention

According to the present disclosure, it is possible to provide a technology with a simpler and smaller configuration and capable of suppressing light leakage from an optical module.

### BRIEF DESCRIPTION OF DRAWINGS

FIG. 1A and FIG. 1B are schematic views of an optical module.

FIG. 2 is an enlarged view of the vicinity of a stepped portion of the optical module.

FIG. 3 is a schematic view of a first modification example of the optical module.

FIG. 4A and FIG. 4B are schematic views of second and third modification examples of the optical module.

FIG. 5 is a schematic view of a fourth modification example of the optical module.

FIG. 6A and FIG. 6B are flowcharts illustrating a method for manufacturing a micro lens array.

FIG. 7 is a flowchart illustrating a method for manufacturing the optical module.

FIG. 8 is a schematic view of distance measuring equipment as an example of a use of the optical module.

FIG. 9 is a schematic view of the micro lens array.

FIG. 10A and FIG. 10B are configuration examples of a known optical module.

### DESCRIPTION OF EMBODIMENTS

Hereinafter, a micro lens array and an optical module according to an embodiment of the present disclosure will be described with reference to the drawings. Note that each of the configurations, combinations thereof, and the like in the embodiment are an example, and various additions, omissions, substitutions, and other changes may be made as appropriate without departing from the spirit of the present disclosure. The present disclosure is not limited by the embodiment and is limited only by the claims.

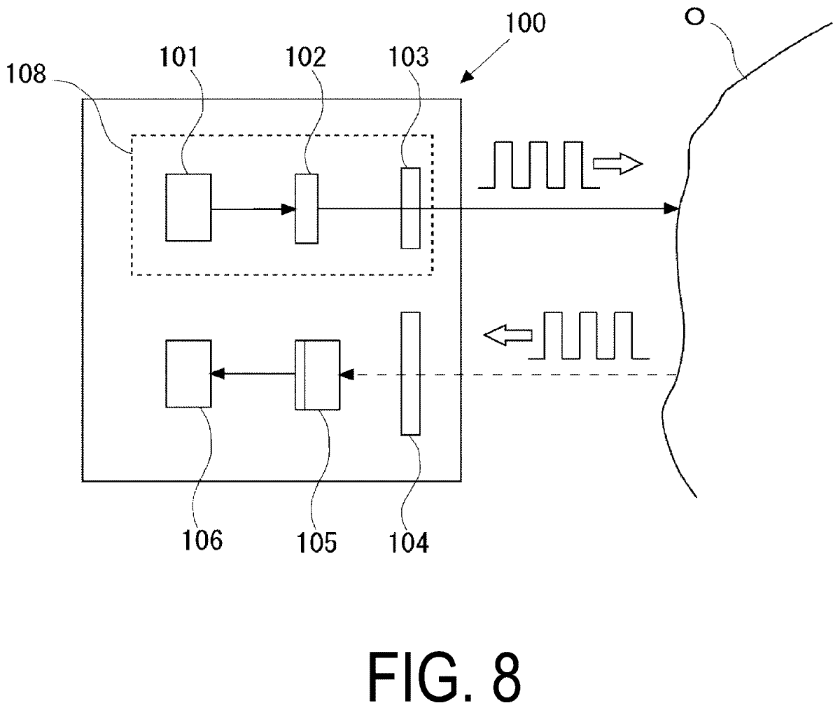

FIG. 8 illustrates a schematic view of distance measuring equipment 100 of a time of flight (TOF) system as an example of a use of the micro lens array and the optical module according to the embodiment. The distance measuring equipment 100 using the TOF system measures a distance to each part of a surface of a measurement target O by measuring the time of flight of irradiation light, and includes a light source control unit 101, an irradiation light source 102, an irradiation optical system 103, a light-receiving optical system 104 that collects reflected light from the measurement target O, a light-receiving device 105, and a signal processing circuit 106.

When the irradiation light source 102 emits pulsed light based on a drive signal from the light source control unit 101, the pulsed light passes through the irradiation optical system 103 and is emitted onto the measurement target O. The reflected light reflected on the surface of the measurement target O passes through the light-receiving optical system 104, is received by the light-receiving device 105, and then is converted into an appropriate electrical signal by the signal processing circuit 106. Then, a calculation unit (not illustrated) measures the distance to each location on the measurement target O by measuring the time from when the irradiation light is irradiated from the irradiation light source 102 until the light-receiving device 105 receives the reflected light, that is, the time of flight of the light.

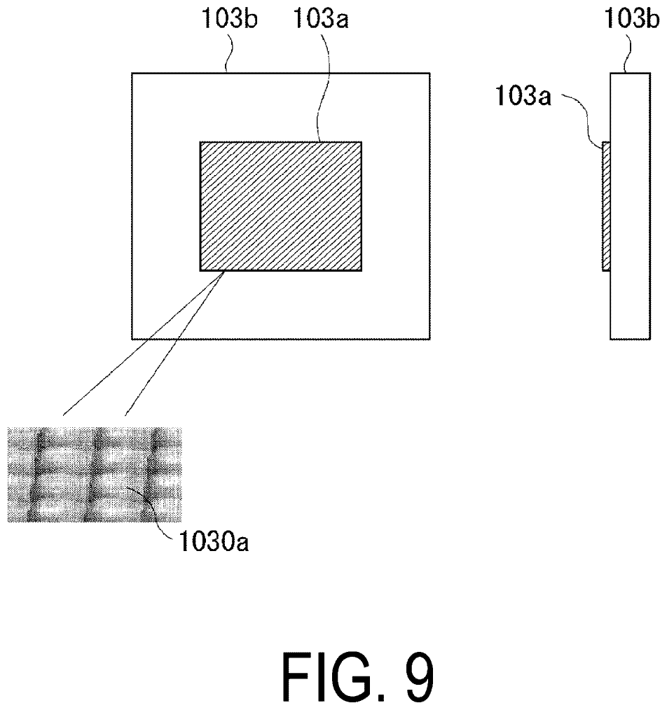

There is a case where a micro lens array is used as the irradiation optical system 103 in the distance measuring equipment 100 of the TOF system. FIG. 9 illustrates a schematic view of a micro lens array. The left view in the figure illustrates a front view of the micro lens array, and the right view in the figure illustrates a side view of the micro lens array. The micro lens array is an optical device including a lens region 103a in which micro lens elements 1030a having a diameter of about 10 μm to several millimeters are arrayed, for example, in a center part of one surface of a substrate portion 103b having a flat plate shape. The lens region 103a may be formed on both surfaces of the substrate portion 103b, or may be formed over the entire surface of the substrate portion 103b.

The function and accuracy of the micro lens array change depending on the shape (spherical, aspherical, cylindrical, hexagonal, and the like) of each of the lens elements 1030a constituting the lens region 103a, the size of the lens element 1030a, the arrangement of the lens elements 1030a, the pitch between the lens elements 1030a, and the like. Then, by unitizing the light source control unit 101, the irradiation light source 102, and the irradiation optical system (micro lens array) 103 and handling them as an optical module 108, assemblability and ease of management of the distance measuring equipment 100 have been improved. The lens element 1030a in the micro lens array corresponds to the optical element of the present disclosure, and the lens region 103a corresponds to the optical region of the present disclosure. Examples of the material of the micro lens array include resin materials such as polycarbonate, PMMA, and cycloolefin copolymerization. The type of material is not particularly limited.

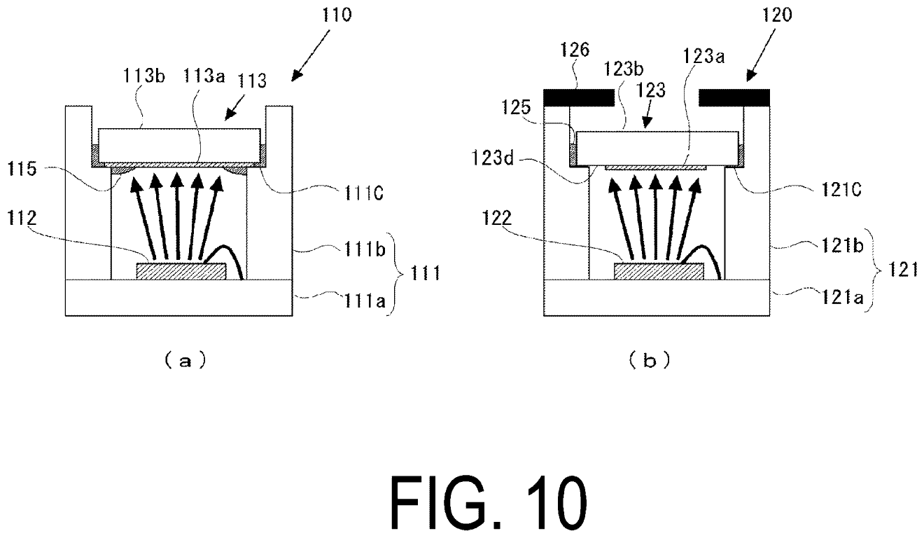

FIG. 10A and FIG. 10B illustrate configuration examples of a known optical module. FIG. 10A illustrates an optical module 110 using a micro lens array 113 in which substantially the entire surface of a lower surface of a substrate portion 113b having a flat plate shape is provided with a lens region 113a where lens elements are arrayed. Here, the optical module 110 includes an enclosure 111 including a base portion 111a on which a light source 112 is installed and a side wall portion 111b surrounding the periphery of the light source 112. The end part of the micro lens array 113 is placed on a stepped portion 111c provided inside the side wall portion 111b, and bonded with an adhesive 115, whereby the micro lens array 113 is fixed to the side wall portion 111b.

In the case of this example, the adhesive 115 may flow out to the lens region 113a due to a capillary phenomenon particularly due to recesses and protrusions of the lens element of the lens region 113a, and affect optical performance in the lens region 113a. Here, for example, even when an adhesive having a high viscosity by a method such as filling with a filler is used, there is a possibility that the adhesive 115 flows out to the lens region 113a due to a capillary phenomenon caused by recesses and protrusions of the lens element.

Next, FIG. 10B illustrates an optical module 120 including a micro lens array 123 in which a center part of a lower surface of a substrate portion 123b having a flat plate shape is provided with a lens region 123a. Here, the optical module 120 includes an enclosure 121 including a base portion 121a on which a light source 122 is installed and a side wall portion 121b surrounding the periphery of the light source 122. The end part of the micro lens array 123 is placed on a stepped portion 121c provided inside the side wall portion 121b, and bonded with an adhesive 125, whereby the micro lens array 123 is fixed to the side wall portion 121b.

In the case of this example, since a peripheral portion 123d as a peripheral region that is a transparent surface on which no lens element is formed exists on the lower surface of the micro lens array 123, the possibility that the adhesive 125 flows out to the lens region 123a and affects the optical performance of the lens region 123a is lower than that in the case of FIG. 10A. However, irradiation light from the light source 122 passes through the peripheral portion 123d, and high-intensity light that is not diffused by the lens element may directly leak to the outside. In this case, there is a possibility of causing what is called an eye-safe problem, where high-intensity leakage light is directly incident on eyes of a person outside.

Therefore, in this example, prevention of direct irradiation of leakage light from the peripheral portion 123d requires a light-blocking lid 126 to be provided at an emission position of the leakage light on an upper side of the micro lens array 123. This results in an increase in manufacturing man-hours and the number of components of the optical module 120, which leads to an increase in the cost of the optical module 120. It is necessary to increase the height of the optical module 120 by the height of the lid 126, which also hinders downsizing of the optical module 120.

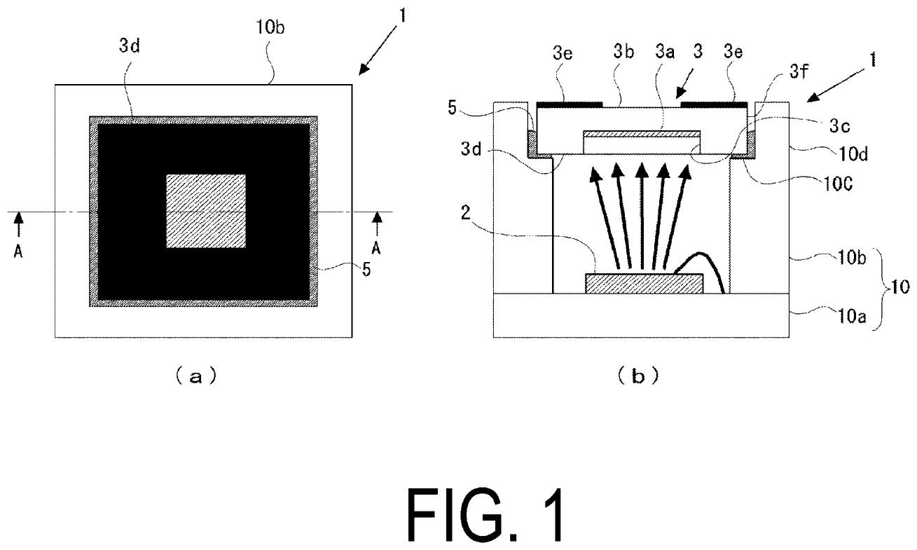

FIG. 1A and FIG. 1B are schematic views of an optical module 1 according to the present embodiment. FIG. 1A is a plan view of the optical module 1, and FIG. 1B is a cross-sectional view taken along line A-A. The optical module 1 includes an enclosure 10 as a holding member, the enclosure 10 including a base portion 10a on which a light source 2 is installed and a side wall portion 10b surrounding the periphery of the light source 2 from four sides. As the light source 2, for example, a vertical cavity surface emitting laser (VCSEL laser) light source is used. A light source control unit (not illustrated) is also placed on the base portion 10a. An inner wall of the side wall portion 10b is provided with a stepped portion 10c as a placement surface having a horizontal surface on which a micro lens array 3 is placed. The micro lens array 3 is placed on a stepped portion 10c and bonded with an adhesive 5, whereby the micro lens array 3 is fixed to the side wall portion 10b. Note that in the present embodiment, the side wall portion 10b has a substantially square shape in plan view; but the shape of the side wall portion 10b in plan view is not limited to this. The side wall portion 10b may have a rectangular shape, a polygonal shape, a circular shape, an elliptical shape, or the like. Examples of the adhesive 5 can include epoxy-based, acrylic-based, and silicone-based adhesives.

The micro lens array 3 includes a substrate portion 3b having a substantially flat plate shape. The substrate portion 3b includes a recessed part 3c having a rectangular shape in plan view at a center part of a lower surface, and a lens region 3a in which lens elements are arrayed is formed on a top surface of the recessed part 3c. A region around the recessed part 3c at the lower surface of the micro lens array 3 constitutes a rib 3d as a peripheral region where an optical function as an optical device is not used. As a result, the thickness of the rib 3d is thicker than the thickness of the recessed part 3c. In the micro lens array 3, this rib 3d is placed on the stepped portion 10c, and the adhesive 5 is interposed between the stepped portion 10c and the rib 3d, whereby the micro lens array 3 is bonded and fixed.

A region on the upper surface of the micro lens array 3 corresponding to the rib 3d is provided with a light-blocking and diffusing portion 3e configured to block or diffuse leakage of irradiation light from the light source 2. This light-blocking and diffusing portion 3e may have only a light-blocking function or only a light-diffusing function. The light-blocking and diffusing portion 3e may have both the light-diffusing function and the light-blocking function. The light-blocking function in the light-blocking and diffusing portion 3e may be a function of completely blocking transmitted light or a function of reducing the intensity of transmitted light. This light-blocking and diffusing portion 3e may be provided by forming a photoresist film having a light-blocking property by, for example, a photolithography technique. The light-blocking and diffusing portion 3e may be provided as a roughened surface by surface roughening by a blasting technique. Note that the surface roughness of the roughened surface is larger than the surface roughness of the substrate portion 3b. The surface roughness of the substrate portion 3b is a surface roughness of a surface of the substrate portion 3b other than the lens region 3a and the light-blocking and diffusing portion 3e. The surface roughness of the substrate portion 3b includes the surface roughness of a side surface 3f of the substrate portion 3b if the entire surfaces of the upper surface and the lower surface of the substrate portion 3b are covered with the lens region 3a and the light-blocking and diffusing portion 3e. The region provided with the light-blocking and diffusing portion 3e is substantially a region corresponding to the rib 3d at the opposite surface of the lens region 3a, but this may not be a region exactly corresponding to the rib 3d, and may be a region including the region corresponding to the rib 3d, or may be a part of the region corresponding to the rib 3d.

According to this configuration, in the optical module 1, irradiation light incident on the rib 3d from the light source 2 is blocked or diffused by the light-blocking and diffusing portion 3e. Therefore, light from the VCSEL laser light source does not directly leak to the front surface of the optical module 1, and it is possible to avoid a risk that high-intensity laser light is directly emitted to the outside.

According to this configuration, the height of an upper end part 10d, which is a thinned part higher than the stepped portion 10c in the side wall portion 10b, can be lowered to a height equivalent to the upper surface of the micro lens array 3, and thus the height of the entire optical module 1 can be lowered.

Furthermore, according to this configuration, since the rib 3d is formed around the lens region 3a of the micro lens array 3, even if the adhesive 5 flows out from the stepped portion 10c, the adhesive 5 is unlikely to reach the lens region 3a, and thus it is possible to suppress influence of the adhesive 5 on the optical characteristics of the micro lens array 3. In the first place, a capillary phenomenon is unlikely to occur on the lower surface of the rib 3d, and the adhesive 5 is unlikely to flow out.

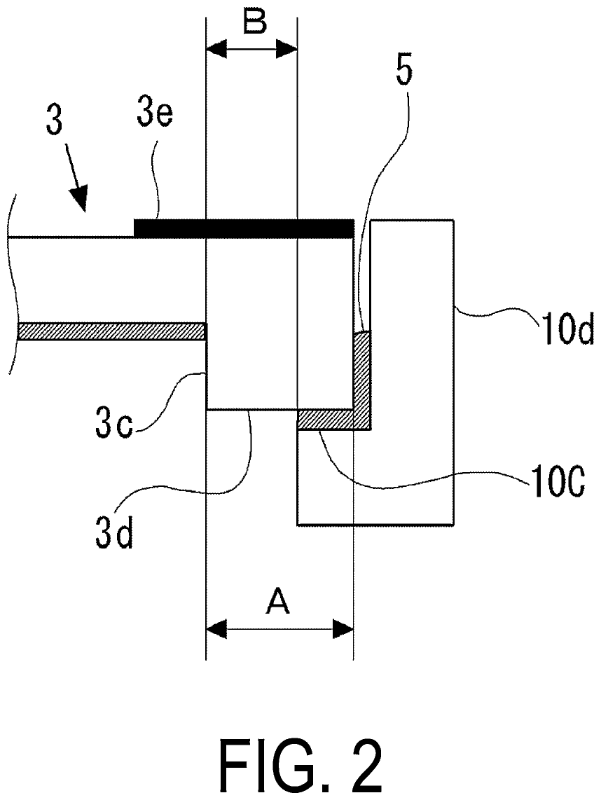

FIG. 2 is an enlarged view of the vicinity of the stepped portion 10c of the optical module 1. In the present embodiment, a relationship of B≥0.3×A is preferably established where A is the width of the rib 3d in the horizontal direction, and B is the distance between the end surface of the recessed part 3c and the end surface of the stepped portion 10c (which is the inner wall of the side wall portion 10b). This can more reliably suppress the adhesive 5 from flowing out from the stepped portion 10c and reaching the lens region 3a of the micro lens array 3. More desirably, a relationship of 0.7×A≥B≥0.5×A is preferably established. This can yet more reliably suppress the adhesive 5 from flowing out from the stepped portion 10c and reaching the lens region 3a of the micro lens array 3. This also makes it possible to ensure a sufficient contact area between the stepped portion 10c and the rib 3d, and stabilize fixation of the micro lens array 3 to the side wall portion 10b. Note that an antireflection film (not illustrated) may be applied to at least one of the lens region 3a or the opposite surface of the lens region 3a in the micro lens array 3 in the present example. This antireflection film may be made of silica (Si), titanium (Ti), or both of them. The antireflection film may be formed with a moth-eye structure. This moth-eye structure may be formed simultaneously in the processing in which the light-blocking and diffusing portion 3e is provided.

### Modification Example 1

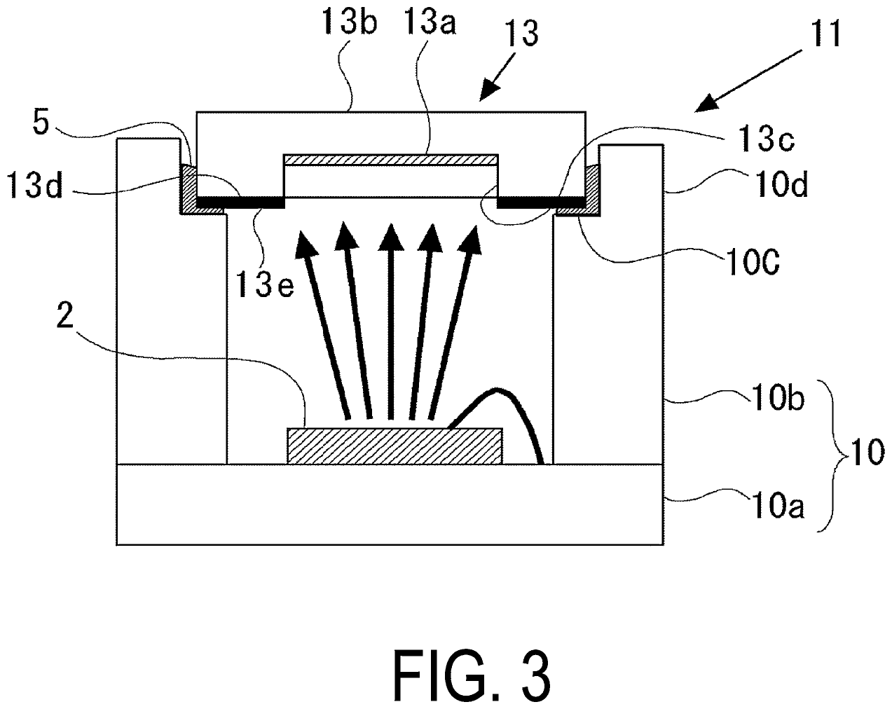

FIG. 3 illustrates a modification example of the present embodiment. This modification example is an example in which a light-blocking and diffusing portion 13e is provided at a rib 13d on the lower surface of a micro lens array 13. This can suppress incidence of irradiation light from the light source 2 on a part other than a lens region 13a of the micro lens array 13, and block or diffuse the leakage light from the source. Therefore, the height of the upper end part 10d of the side wall portion 10b can be further lowered. This also makes it possible to suppress occurrence of flare caused by stray light 30) in the micro lens array 3.

### Modification Examples 2 and 3

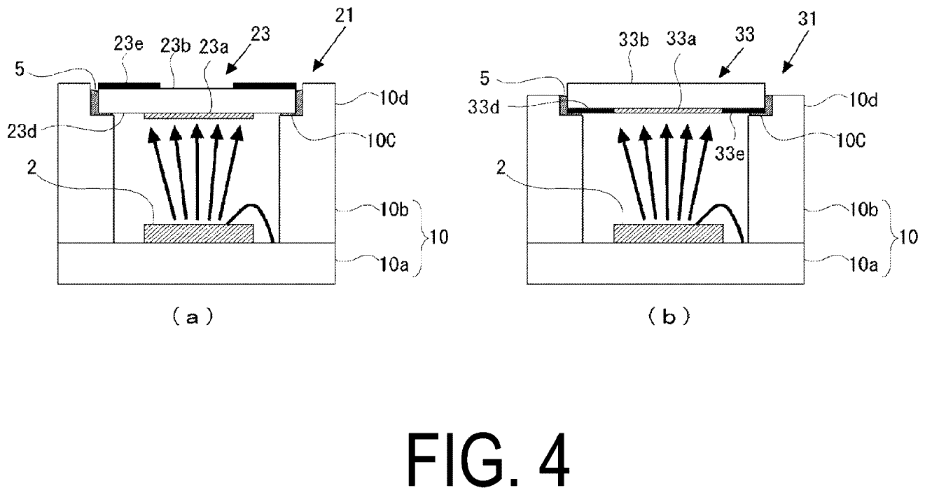

FIG. 4A illustrates a second modification example of the present embodiment. In this modification example, a micro lens array 23 is not provided with a recessed part, and a lens region 23a is directly provided at a lower surface of a substrate portion 23b. A light-blocking and diffusing portion 23e is provided at an upper surface of the substrate portion 23b. In other words, in this modification example, the lens region 23a and a peripheral portion 23d as a peripheral region around the lens region 23a are arranged at substantially the same plane. In this manner, since the rib can be omitted, the heights of the micro lens array 23 and the upper end part 10d can be lowered, and the height of the optical module 21 can be lowered.

FIG. 4B illustrates a third modification example of the present embodiment. In this modification example, a micro lens array 33 is not provided with a recessed part and a lens region 33a is directly provided at a lower surface of a substrate portion 33b. Then, a light-blocking and diffusing portion 33e is provided at a peripheral portion 33d as a peripheral region around the lens region 33a at a lower surface of the substrate portion 33b. In this manner, since the rib can be omitted, the height of the micro lens array 33 can be lowered. It is possible to suppress incidence of irradiation light from the light source 2 on a part other than a lens region 33a of the micro lens array 33, and block or diffuse the leakage light from the source. Therefore, the height of the upper end part 10d of the side wall portion 10b can be further lowered. This also makes it possible to suppress occurrence of flare caused by stray light in the micro lens array 33.

### Modification Example 4

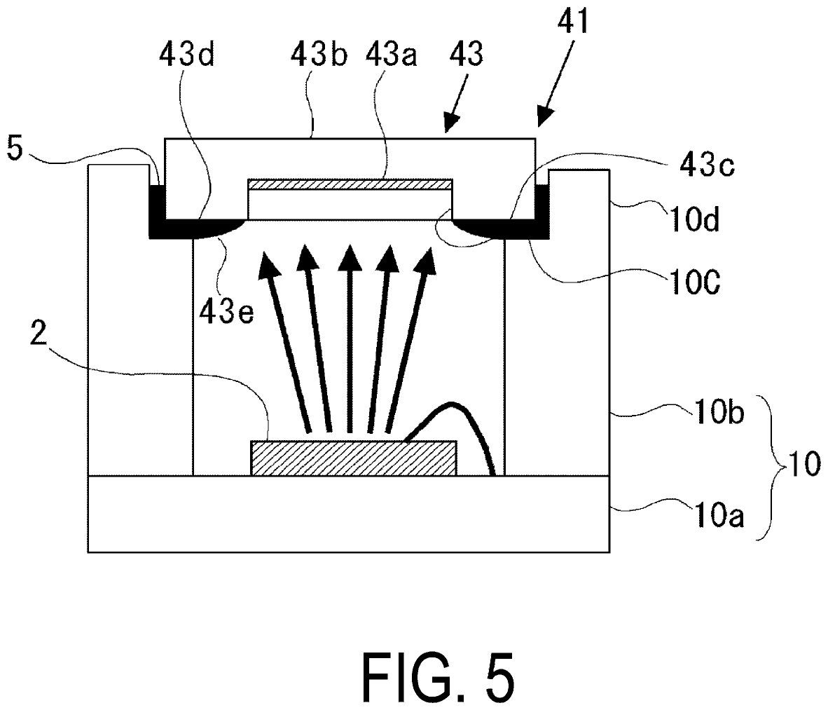

FIG. 5 illustrates a fourth modification example of the present embodiment. In this modification example, a light-blocking and diffusing portion 43e is provided at a rib 43d at a lower surface of a micro lens array 43 using the adhesive 5. In other words, in this modification example, as the adhesive interposed between the rib 43d of the micro lens array 43 and the stepped portion 10c of the side wall portion 10b and bonding them together, the adhesive 5 is used that is colored and that has a light-blocking property with respect to incident light from the light source 2.

Then, this adhesive is also distributed on the surface of the rib 43d to form the light-blocking and diffusing portion 43e. This can suppress incidence of irradiation light from the light source 2 on a part other than a lens region 43a of the micro lens array 43, and block or diffuse the leakage light from the source. Therefore, the height of the upper end part 10d of the side wall portion 10b can be further lowered. This also makes it possible to suppress occurrence of flare caused by stray light in the micro lens array 43.

Here, the light-blocking and diffusing portion 43e that uses this adhesive 5 may be formed only with the adhesive 5, or may be used in combination with, for example, a photoresist film having a light-blocking property by a photolithography technique or surface roughening by a blasting technique.

### Method for Manufacturing Micro Lens Array

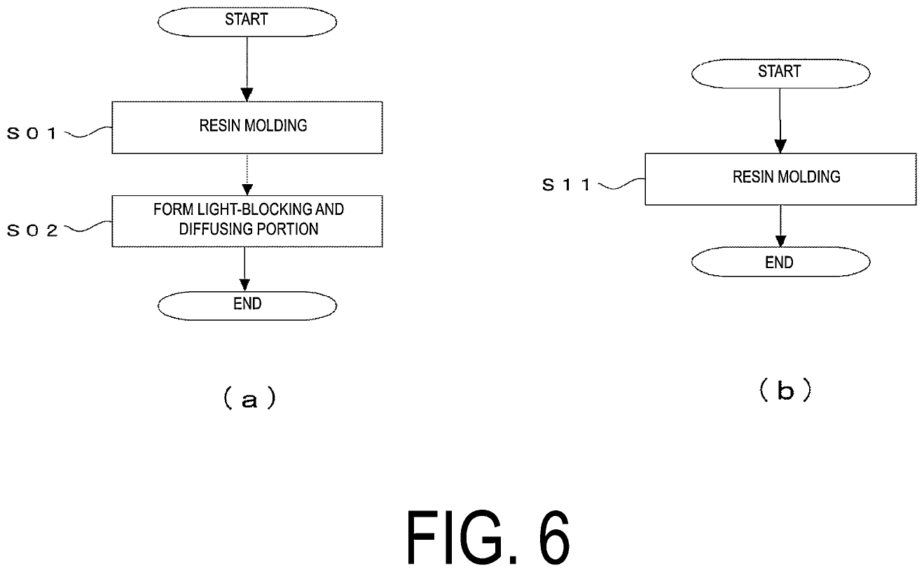

Next, the method for manufacturing the micro lens array 3 will be described. FIG. 6A and FIG. 6B are flowcharts describing a flow of the method for manufacturing. In the example illustrated in FIG. 6A, as illustrated in S01, in the micro lens array 3, the substrate portion 3b, the lens region 3a, the recessed part 3c, and the rib 3d are simultaneously formed with integral molding by resin molding. Step S01 corresponds to the forming. Thereafter, as illustrated in S02, the light-blocking and diffusing portion 3e is formed. Forming this light-blocking and diffusing portion 3e is performed using the following method, for example.

### (1) Photolithography

A photoresist liquid is applied to the upper surface or the lower surface of the micro lens array 3 having been integrally molded. Then, with a part other than the rib 3d on the lower surface or a part other than the region corresponding to the rib 3d on the upper surface covered with a photomask, exposure is performed. Then, the non-photosensitive parts are removed to form a light-blocking layer made of a photoresist material in the rib 3d or the region corresponding to the rib 3d in the upper surface.

### (2) Blasting

With a part other than the rib 3d on the lower surface or a part other than the region corresponding to the rib 3d on the upper surface covered with a mask, air containing an abrasive is caused to collide with the upper surface or the lower surface of the micro lens array 3 to roughen the surface.

### (3) Others

With a part other than the rib 3d on the lower surface or a part other than the region corresponding to the rib 3d on the upper surface covered with a mask, the resin surface is altered by a chemical, thermal, or optical method to roughen the surface.

When the forming of the light-blocking and diffusing portion 3e is completed, the present routine is ended. Step S02 corresponds to the forming the light-blocking and diffusing portion. Note that when the methods (2) and (3) are performed in step S02, the step corresponds to the roughening

In the example illustrated in FIG. 6B, the surface of a part that forms the light-blocking and diffusing portion 3e is roughened in advance by the method of (2) or (3) above in the mold for resin molding. In the manufacturing of the micro lens array 3, the substrate portion 3b, the lens region 3a, the recessed part 3c, the rib 3d, and the light-blocking and diffusing portion 3e are simultaneously formed with integral molding by resin molding. According to this example, the manufacturing of the micro lens array 3 can be further simplified.

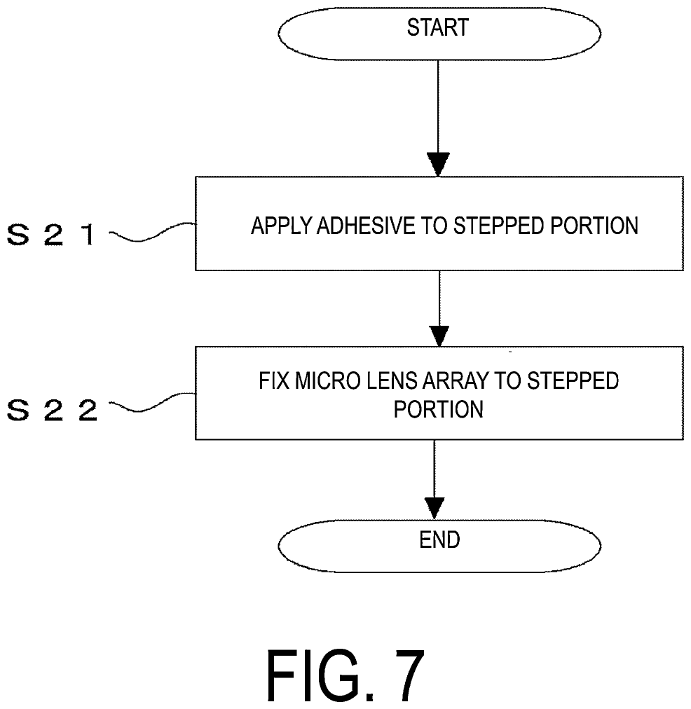

Next, FIG. 7 illustrates a flowchart when the optical module 1 is manufactured. When the optical module 1 is manufactured, an adhesive is applied to the stepped portion 10c of the side wall portion 10b in step S21. In this state, in step S22, the micro lens array 3 is placed and fixed onto the stepped portion 10c. Applying the adhesive to the stepped portion 10c of the side wall portion 10b corresponds to the applying the adhesive, and placing and fixing the micro lens array 3 onto the stepped portion 10c corresponds to the fixing.

Note that in the above embodiment, the example has been described in which the lens regions 3a, 13a, 23a, 33a, and 43a in the micro lens arrays 3, 13, 23, 33, and 43 are provided on one surface on the light source 2 side, respectively, but the lens region may be arrayed on one surface on the opposite side of the light source 2. Furthermore, the lens regions may be arrayed on both sides.

A micro lens array having functions equivalent to those of the micro lens arrays 3, 13, 23, 33, and 43 described in the present embodiment may be used as an optical system for image photographing, for face authentication in a security instrument, or for space authentication in a vehicle or a robot. In the present embodiment, the description has been made on the assumption that the material of the micro lens arrays 3, 13, 23, 33, and 43 is a resin material, but when a resin material is used, a thermosetting resin or a photocurable resin may be used in addition to a thermoplastic resin. The material of the micro lens arrays 3, 13, 23, 33, and 43 is not limited to this. A material of the optical device constituting the optical modules 1, 11, 21, 31, and 41 may be resin or another material such as glass. For example, a combination of a resin material and a glass material may be a combination of a structure in which a lens array of resin is affixed to a glass material. Also, glass molding may be employed instead of resin molding for the method for manufacturing the micro lens array.

In the optical modules 1, 11, 21, 31, and 41 in the present embodiment, an example has been described in which a micro lens array is used as an optical device, but optical devices other than the micro lens array may be used as the optical device. For example, an optical device including a single lens, a Fresnel lens, or a diffraction grating can be used as the optical element.

### Wiring of Electrically Conductive Substance

Note that wiring containing an electrically conductive substance may be provided on the surface or inside of the micro lens array 3, 13, 23, 33, or 43 according to the present embodiment, and damage to each lens element in the lens regions 3a, 13a, 23a, 33a, or 43a may be detectable by monitoring the conduction state of the wiring. This makes it possible to easily detect damage such as cracking and peeling of each lens element, and thus it becomes possible to prevent loss due to defect or malfunction of the optical modules 1, 11, 21, 31, and 41 caused by damage to the micro lens arrays 3, 13, 23, 33, and 43. For example, detecting generation of a crack in each lens element by disconnection of the electrically conductive substance and blocking light emission of the light source can avoid transmission of 0th-order light from the light source directly through the micro lens arrays 3, 13, 23, 33, and 43 via the crack and its emission to the outside. As a result, it is possible to further improve the eye-safety performance of the device.

The wiring of the electrically conductive substance may be provided at the peripheral portions (or ribs) 3d, 13d, 23d, 33d, and 43d of the micro lens array or on or over lens regions 3a, 13a, 23a, 33a, and 43a. The wiring of the conductive substance may be provided at the surface on which the lens regions 3a, 13a, 23a, 33a, and 43a are formed, the surface on the opposite side, or the surfaces on both sides. The electrically conductive substance is not particularly limited as long as it has electrical conductivity, and for example, metal, metal oxide, electrically conductive polymer, electrically conductive carbon-based substance, or the like can be used.

More specifically; the metal include gold, silver, copper, chromium, nickel, palladium, aluminum, iron, platinum, molybdenum, tungsten, zinc, lead, cobalt, titanium, zirconium, indium, rhodium, ruthenium, alloys thereof, and the like. Examples of the metal oxide include chromium oxide, nickel oxide, copper oxide, titanium oxide, zirconium oxide, indium oxide, aluminum oxide, zinc oxide, tin oxide, or composite oxides thereof such as composite oxides of indium oxide and tin oxide (ITO) and composite oxide of tin oxide and phosphorus oxide (PTO). Examples of the electrically conductive polymer include polyacetylene, polyaniline, polypyrrole, and polythiophene. Examples of the electrically conductive carbon-based substance include carbon black, SAF, ISAF, HAF, FEF, GPF, SRF, FT, MT, pyrolytic carbon, natural graphite, and artificial graphite. These electrically conductive substances can be used alone, or two or more types thereof can be used in combination.

For the electrically conductive substance, a metal or a metal oxide, which is excellent in electrical conductivity and with which it is easy to form wiring, is preferable, a metal is more preferable, gold, silver, copper, indium, and the like are preferable, and silver is preferable in that silver is mutually fused at a temperature of about 100° C. and wiring excellent in electrical conductivity can be formed even on a resin micro lens array. A pattern and a shape of the wiring of the electrically conductive substance is not particularly limited. A pattern surrounding the periphery of the micro lens arrays 3, 13, 23, 33, and 43 may be adopted, or the pattern may have a complicated shape to further improve the detectability of cracks and the like. A pattern in which a transparent electrically conductive substance covers at least a part of the micro lens arrays 3, 13, 23, 33, and 43 may also be adopted.

### REFERENCE SIGNS LIST

3, 13, 23, 33, 43 Micro lens array
3a, 13a, 23a, 33a, 43a Lens region
3b, 13b, 23b, 33b, 43b Substrate portion
3c, 13c, 43c Recessed part
3d, 13d, 43d rib
23d, 33d Peripheral portion
3e, 13e, 23e, 33e, 43e Light-blocking and diffusing portion
2 Light source
5 Adhesive
10 Enclosure
10a Base portion
10b Side wall portion
10c Stepped portion
10d Upper end part
100 TOF distance measuring equipment
101 Light source control unit
102 Light source
103 Irradiation optical system
104 Light-receiving optical system
105 Light-receiving device
106 Signal processing circuit

1: An optical device comprising:
an optical region in which an optical element is arranged, at a part of at least one surface of a substrate portion having a flat plate shape;
a peripheral region in which the optical element is not arranged, the peripheral region being provided around the optical region at a surface, of the substrate portion, provided with the optical region; and
a light-blocking and diffusing portion provided at the peripheral region and/or a region corresponding to the peripheral region at an opposite surface of the substrate portion, the light-blocking and diffusing portion being configured to suppress transmission of light or diffuse light.

2: The optical device according to claim 1, wherein
in the substrate portion, the optical region is formed at a surface recessed with respect to the peripheral region.

3: The optical device according to claim 1, wherein
the optical element is a lens element, and the optical region is a lens region in which a plurality of the lens elements are arrayed.

4: The optical device according to claim 1, wherein
the light-blocking and diffusing portion includes a film of a photoresist material formed at the peripheral region and/or the region corresponding to the peripheral region at the opposite surface of the substrate portion.

5: The optical device according to claim 1, wherein
the light-blocking and diffusing portion includes a roughened surface in which surface roughness of the peripheral region and/or the region corresponding to the peripheral region at the opposite surface of the substrate portion is larger than that of a side surface of the substrate portion.

6: An optical module comprising:
the optical device according to claim 1;
a light source configured to cause light to be incident on the optical device; and
a holding member holding the optical device and the light source, wherein
the holding member includes a base portion to which the light source is fixed and a side wall portion to which the optical device is fixed,
the side wall portion is provided with a placement surface at which the peripheral region of the optical device is placed, and
a predetermined adhesive is interposed between the peripheral region and the placement surface.

7: The optical module according to claim 6, wherein
an upper end of the side wall portion is formed to be at the same height as an upper surface of the optical device or lower than the upper surface of the optical device.

8: The optical module according to claim 6, wherein
the predetermined adhesive has a light-blocking property and forms the light-blocking and diffusing portion.

9: A method for manufacturing an optical device including an optical region in which an optical element is arranged, at a part of at least one surface of a substrate portion having a flat plate shape, the method comprising:
forming, with integral molding, the substrate portion having the flat plate shape, the optical region, and a peripheral region that is arranged around the optical region and in which an optical function as the optical device is not used; and
forming a light-blocking and diffusing portion at the peripheral region and/or a region corresponding to the peripheral region at an opposite surface of the substrate portion, the light-blocking and diffusing portion being configured to suppress transmission of light or diffuse light.

10: The method for manufacturing an optical device according to claim 9, wherein
the forming the light-blocking and diffusing portion is performed simultaneously with the forming, and
in the forming, a roughened surface in which surface roughness of the peripheral region and/or the region corresponding to the peripheral region at the opposite surface of the substrate portion is larger than that of a side surface of the substrate portion is molded as the light-blocking and diffusing portion.

11: The method for manufacturing an optical device according to claim 9, wherein
the forming the light-blocking and diffusing portion is performed after the forming, and includes forming a film of a photoresist material by photolithography at a surface of the peripheral region and/or the region corresponding to the peripheral region at the opposite surface of the substrate portion, the peripheral region and the substrate portion having been molded in the forming.

12: The method for manufacturing an optical device according to claim 9, wherein
the forming the light-blocking and diffusing portion is performed after the forming, and includes roughening a surface of the peripheral region and/or the region corresponding to the peripheral region at the opposite surface of the substrate portion, the peripheral region and the substrate portion having been molded in the forming.

13: A method for manufacturing the optical module according to claim 6, the method comprising:
applying the predetermined adhesive to the placement surface; and
placing and fixing the optical device at the placement surface applied with the predetermined adhesive.

14: The method for manufacturing the optical module according to claim 13, wherein
the predetermined adhesive has a light-blocking property.

15: The optical device according to claim 2, wherein
the optical element is a lens element, and the optical region is a lens region in which a plurality of the lens elements are arrayed.

16: The optical device according to claim 2, wherein
the light-blocking and diffusing portion includes a film of a photoresist material formed at the peripheral region and/or the region corresponding to the peripheral region at the opposite surface of the substrate portion.

17: The optical device according to claim 2, wherein
the light-blocking and diffusing portion includes a roughened surface in which surface roughness of the peripheral region and/or the region corresponding to the peripheral region at the opposite surface of the substrate portion is larger than that of a side surface of the substrate portion.

18: An optical module comprising:
the optical device according to claim 2;
a light source configured to cause light to be incident on the optical device; and
a holding member holding the optical device and the light source, wherein
the holding member includes a base portion to which the light source is fixed and a side wall portion to which the optical device is fixed,
the side wall portion is provided with a placement surface at which the peripheral region of the optical device is placed, and
a predetermined adhesive is interposed between the peripheral region and the placement surface.

19: The optical module according to claim 18, wherein
an upper end of the side wall portion is formed to be at the same height as an upper surface of the optical device or lower than the upper surface of the optical device.

20: The optical module according to claim 18, wherein
the predetermined adhesive has a light-blocking property and forms the light-blocking and diffusing portion.
